(19) United States
(12) Patent Application Publication
(10) Pub. No.: US 2007/0108893 A1
(43) Pub. Date: May 17, 2007

(54) Organic light emitting device

(76) Inventors: Kwan-Hee Lee, Suwon-si (KR); Ja-Hyun Im, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/595,261

(22) Filed: Nov. 9, 2006

(30) Foreign Application Priority Data
Nov. 16, 2005 (KR) 10-2005-0109520

(51) Int. Cl. H01L 51/00

(52) U.S. Cl. 313/504

(57) ABSTRACT

An organic light-emitting device (OLED) is disclosed. The OLED includes a pixel electrode; a counter electrode; and at least an emission layer between the pixel electrode and the counter electrode, wherein a total thickness of the organic layer including an emission layer emitting blue light is 3000-3600 Å. According to the OLED of the present disclosure, the incidence of dark spots can be remarkably reduced without degradation of color purity and efficiency, and thus the flat display including the OLED has improved reliability.

### CROSS-REFERENCE TO RELATED APPLICATION

This application claims the benefit of Korean Patent Application No. 10-2005-0109520, filed on Nov. 16, 2005, in the Korean Intellectual Property Office, the disclosure of which is incorporated herein in its entirety by reference.

### BACKGROUND

1. Field

The present disclosure relates to an organic light emitting device (OLED), and more particularly, to an OLED including a blue light emission layer.

2. Description of the Related Technology

Organic light emitting display devices are self-emission displays that emit light by recombination of electrons and holes in an organic layer made of a fluorescent or phosphorescent compound when a current is applied to the organic layer. Organic light emitting display devices are lightweight, have simple elements, and are easy to fabricate. In addition, organic light emitting display devices have superior image quality, and have a wide viewing angle. Furthermore, organic light emitting display devices can display dynamic images of high quality with high color purities. Organic light emitting display devices also have electrical properties such as low power consumption and low driving voltage suitable for portable electronic devices.

Organic light emitting display devices typically include organic light emitting devices (OLEDs), each including an organic layer interposed between two electrodes. In OLEDs, a multi-layer structure including an electron injection layer (EIL), an emission layer (EML), a hole transport layer (HTL), and the like can be used instead of a single EML for improving efficiency and for reducing driving voltage. For example, an OLED including a HTL is disclosed in Japanese Patent Application Publication No. 2002-252089.

Organic light emitting display devices include an array of pixels, typically, red, green, and blue pixels. Each pixel includes an organic layer including a light emission layer. A blue pixel includes a blue light emission layer. One approach has blue pixels including an organic layer having a thickness between about 1,800 and about 2,200 Å. However, progressive dark spots in the OLEDs may be generated because of the thickness of the organic layer. Therefore, there is a need to solve this problem. The following embodiments address this and others as well.

### SUMMARY

One embodiment provides an organic light-emitting device comprising: a first electrode; a second electrode; and an organic layer interposed between the first and second electrodes, the organic layer comprising an emission layer emitting blue light, wherein the organic layer has a thickness between about 3,000 Å and about 3,600 Å.

The organic layer may further comprise at least one layer selected from the group consisting of a hole injection layer, a hole transport layer, an electron blocking layer, a hole blocking layer, an electron transport layer and an electron injection layer. The organic layer may further comprise a hole injection layer, a hole transport layer and an electron transport layer. A total thickness of the hole injection layer and hole transport layer may be between about 2,400 Å and about 3,000 Å.

The hole injection layer may comprise at least one material selected from the group consisting of triphenylamine (TCTA), m-MTDATA, Polyaniline/Dodecylbenzenesulfonic acid (Pani/DBSA) and Poly(3,4-ethylenedioxythiophene)/Poly(4-styrenesulfonate) (PEDOT/PSS) which are amines having copper phthalocyanine (CuPc) or starburst amines. The hole transport layer may comprise at least one material selected from the group consisting of 1,3,5-tricarbazolylbenzene, 4,4′-bis carbazolylbiphenyl, polyvinylcarbazole, m-bis carbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-il)-N,N′-diphenylbenzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB) and poly(9,9-dioctylfluorene-co-bis-(4-butylphenyl-bis-N,N-phenyl-1,4-phenylenediamin)) (PFB).

The emission layer may have a thickness between about 100 Å and about 500 Å. The emission layer may have a thickness between about 100 Å and about 400 Å.

The first electrode may comprise a transparent material. The second electrode may comprise a transparent material. The first and second electrodes may comprise a transparent material. The device may further comprise a thin film transistor comprising source and drain electrodes, wherein the first electrode of the organic light-emitting device is electrically connected to one of the source and drain electrodes.

Another embodiment provides an organic light emitting display device, comprising: an array of pixels, the pixels comprising a blue light emitting pixel, wherein the blue light emitting pixel comprises: a first electrode, a second electrode, and an organic layer interposed between the first and second electrodes, the organic layer comprising an emission layer emitting blue light; and wherein the organic layer has a thickness between about 3,000 Å and about 3,600 Å.

The organic layer may further comprise at least one layer selected from the group consisting of a hole injection layer, a hole transport layer, an electron blocking layer, a hole blocking layer, an electron transport layer and an electron injection layer. The organic layer may further comprise a hole injection layer, a hole transport layer and an electron transport layer. A total thickness of the hole injection layer and hole transport layer may be between about 2,400 Å and about 3,000 Å.

The emission layer may have a thickness between about 100 Å and about 500 Å. The emission layer may have a thickness between about 100 Å and about 400 Å. The pixels may further comprise a red light emitting pixel comprising an organic layer which comprises an emission layer emitting red light, and the organic layer may have a thickness between about 2,700 Å and about 3,300 Å. The pixels may further comprise a green light emitting pixel comprising an organic layer which comprises an emission layer emitting green light, and the organic layer may have a thickness between about 2,200 Å and about 2,800 Å.

Another embodiment provides an organic light emitting device (OLED) in which an incidence of dark spots is remarkably reduced by regulating the thickness of an organic layer including an emission layer (EML) emitting blue light, and a flat display including the OLED.

Another embodiment provides an organic light-emitting device including an organic layer which includes a pixel electrode, an counter electrode, and at least an emission layer between the pixel electrode and the counter electrode, wherein a total thickness of the organic layer comprising an emission layer emitting blue light is about 3000 to about 3600 Å.

According to the OLED of the embodiments described below, an incidence of dark spots can be minimized without degradation of color purity and efficiency. Thus, a flat display including the OLED has improved reliability.

### BRIEF DESCRIPTION OF THE DRAWINGS

The above and other features and advantages of the instant disclosure will become more apparent by describing certain embodiments thereof with reference to the attached drawings in which:

FIG. 1 illustrates schematically a structure of an organic light emitting device (OLED) according to an embodiment;

FIG. 2 is a graph illustrating photoluminescent (PL) intensities of the OLED of FIG. 1 according to an embodiment; and

FIG. 3 is a graph illustrating y color coordinates of the OLED of FIG. 1 according to an embodiment.

### DETAILED DESCRIPTION

Certain embodiments will now be described more fully with reference to the accompanying drawings.

An organic light emitting device (OLED) according to an embodiment includes a pixel electrode and a counter electrode, and an organic layer including at least an emission layer (EML) between the pixel electrode and the counter electrode. The emission layer is configured to emit blue light. The total thickness of the organic layer including the EML is about 3000 to about 3600 Å.

When patterning the pixel electrode of the OLED, various conductive or non-conductive particles may be generated. Also, when washing after patterning the pixel electrode, various particles may remain on the pixel electrode. The average diameter of the particles is generally about 2000 Å or less. When such particles remain in a pixel part, deposition coverage may be poor. Since the OLED is current-driven, dark spots caused by the particles interposed between the pixel electrode and the counter electrode may occur. However, it is very difficult to prevent the generation of these particles and to completely remove the generated particles. Such a phenomenon may occur particularly in the organic layer including the EML which emits blue light which is the thinnest layer in the organic layer of the OLED.

In one embodiment, the total thickness of the organic layer including the EML emitting blue light in the OLED is about 3,000 to about 3,600 Å. The total thickness of the organic layer including the EML emitting blue light is greater than about 2,000 Å which is the average diameter of conductive or non-conductive particles which may exist in the pixel part. Accordingly, dark spots can be considerably reduced in the OLED according to one or more of the instant embodiments without degradation of color purity and efficiency.

In another embodiment, the total thickness of the organic layer including the EML emitting blue light may be selected to permit a maximum emission of blue light through at least one of the pixel and counter electrodes. In a display device including the OLED, at least one of the pixel and counter electrodes can be formed of an at least partially transparent material so that light can emit therethrough from the organic layer. Some portion of light, however, is reflected by the at least partially transparent material and causes interference within the organic layer between the two electrodes. To maximize light emission, the thickness of the organic layer can be selected such that the reflected portion of light creates a constructive resonance between the electrodes.

In the OLED as described above, the organic layer including the EML emitting blue light may further include at least one selected from the group consisting of a hole injection layer (HIL), a hole transport layer (HTL), an electron blocking layer (EBL), a hole blocking layer (HBL), an electron transport layer (ETL) and an electron injection layer (EIL). In the OLED according to an embodiment, the organic layer including the EML emitting blue light may further include a HIL, a HTL and an ETL.

In one embodiment, when the total thickness of the HIL and the HTL is less than about 2,400 Å or greater than about 3,000 Å, since hole injection properties and hole transport properties, which are suitable for the resonance effect of the EML emitting blue light, may not be implemented, color purity and efficiency may be reduced. However, it will be understood by those of ordinary skill in the art that various changes in the thickness of the HIL and the HTL may be made depending on the desired properties of the EML.

In an OLED according to another embodiment, the total thickness of an organic layer including an EML emitting red light may be about 2,700 to about 3,300 Å. In addition, in an OLED according to another embodiment, the total thickness of an organic layer including an EML emitting green light may be about 2,200 to about 2,800 Å. The thicknesses of the organic layer including the EML emitting red light and the organic layer including the EML emitting green light are adjusted so as to transport holes and electrons effectively according to the resonance effects of the EML emitting red light and EML emitting green light. When the thickness of the organic layer including the EML emitting red light is greater than about 3,300 Å or the thickness of the organic layer including the EML emitting green light is greater than about 2,800 Å, driving voltages may be higher.

Hereinafter, an OLED according to an embodiment and a method of manufacturing the OLED will be described with reference to FIG. 1. Referring to FIG. 1, the OLED includes a substrate, a pixel electrode, a HIL, a HTL, an EML, a HBL, an ETL and an EIL which are stacked sequentially.

First, the pixel electrode is formed over the substrate. Here, the substrate may be formed of any material suitable for an OLED. However, the substrate may be a glass substrate or a plastic substrate, depending on the desired characteristics such as transparency, surface smoothness, ease of handling, water tightness, and the like. The pixel electrode may be a transparent electrode or a reflective electrode including a metal having excellent conductivity. Examples of materials for the pixel electrode include, but are not limited to, lithium (Li), magnesium (Mg), aluminum (Al), aluminum-lithium (Al-Li), calcium (Ca), magnesium-indium (Mg—In), magnesium-silver (Mg—Ag), calcium (Ca)-aluminum (Al), aluminum (Al)-indium tin oxide (ITO), indium tin oxide (ITO), indium zinc oxide (IZO), and the like. It will be understood by those of ordinary skill in the art that various changes may be made to the pixel electrode without departing from the spirit and scope of the these embodiments.

Next, the HIL may be formed over the pixel electrode using various methods such as vacuum evaporation methods, spin coating methods, casting methods, Langmuir-Blodgett (LB) methods, and the like. which are known to those of ordinary skill in the art.

When the HIL is formed using a vacuum evaporation method, deposition conditions may differ according to compounds used as materials of the HIL, structures and thermal properties of the HIL, and the like. In one embodiment, the deposition conditions may include a deposition temperature of about 100° C. to about 500° C., an air pressure of about 10⁻⁸ torr to about 10⁻³ torr, and a deposition velocity of about 0.01 Å/sec to about 100 Å/sec.

When the HIL is formed using a spin coating method, coating conditions differ according to compounds used as materials of the HIL, structures and thermal properties of the HIL, and the like. In one embodiment, the coating conditions may include a coating velocity of about 2000 rpm to about 5000 rpm, and a heat treatment temperature of about 80° C. to about 200° C. for removing a solvent after coating.

The materials of the HIL may be selected from hole injection materials which are known to those of ordinary skill in the art, but are not limited thereto. Examples of the hole injection materials include copper phthalocyanine (CuPc), 4,4′,4″-tris(-carbazolyl)-triphenylamine (TCTA), 4,4′,4″-tris(3-methylphenylphenylamino)-triphenylamine (m-MTDATA), IDE406 (available from Idemitsu Kosan Co., Ltd., Tokyo, Japan), Polyaniline/Dodecylbenzenesulfonic acid (Pani/DBSA) and Poly(3,4-ethylenedioxythiophene)/Poly(4-styrenesulfonate) (PEDOT/PSS), but the hole injection materials are not limited thereto. Formulas of some of the foregoing materials are shown below.

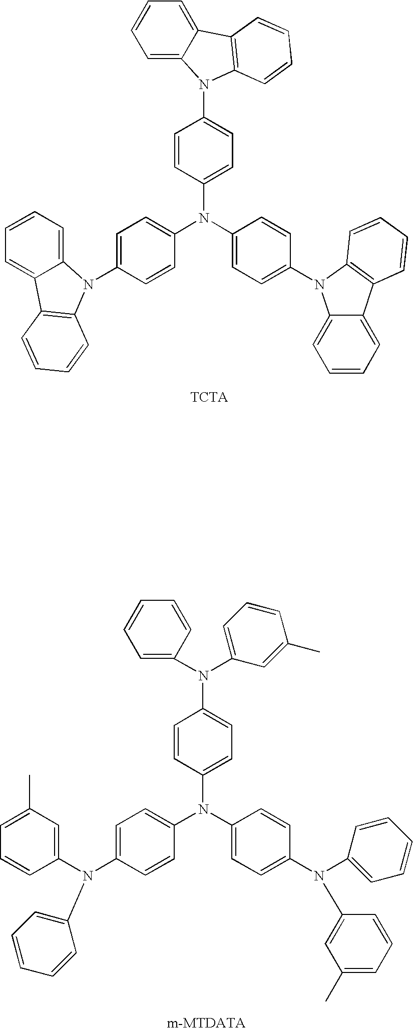

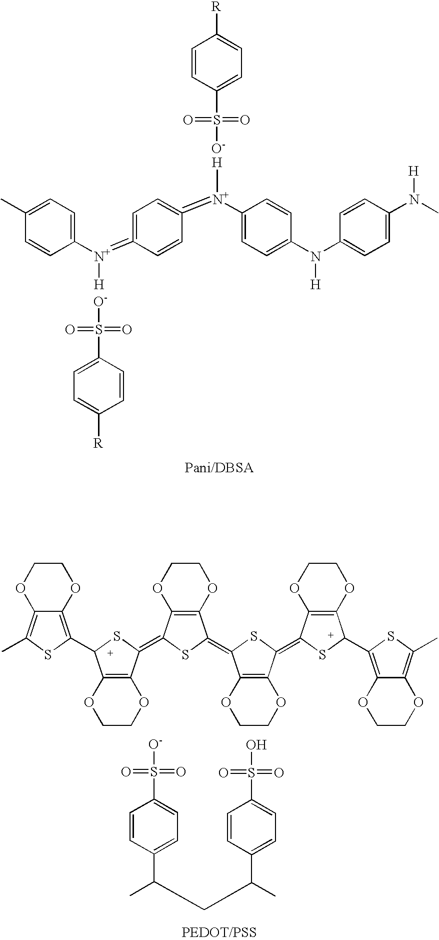

Next, the HTL may be formed over the HIL using various methods such as vacuum evaporation methods, spin coating methods, casting methods, LB methods, and the like. When the HTL is formed using vacuum evaporation methods and spin coating methods, deposition conditions and coating conditions differ according to compounds used as materials of the HTL. In one embodiment, the deposition conditions and the coating conditions may be substantially the same as the deposition conditions and coating conditions used to form the HIL.

The materials of the HTL may be selected from hole transport materials which are known to those of ordinary skill in the art, but are not limited thereto. Examples of the hole transport materials may include 1,3,5-tricarbazolylbenzene, 4,4′-biscarbazolylbiphenyl, polyvinylcarbazole, m-biscarbazolylphenyl, 4,4′-biscarbazolyl-2,2′-dimethyl biphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-il)-N,N′-diphenyl benzidine (α-NPD), N,N′-diphenyl-N,N′-bis(1-naphthyl)-(1,1′-biphenyl)-4,4′-diamine (NPB), IDE320 (available from Idemitsu Kosan Co., Ltd., Tokyo, Japan), poly(9,9-dioctylfluorene-co-N-(4-butylphenyl)diphenyl amine) (TFB) and poly(9,9-dioctylfluorene-co-bis-(4-butylphenyl-bis-N,N-phenyl-1,4-phenylenediamin)) (PFB), and the like, but the hole transport materials are not limited thereto.

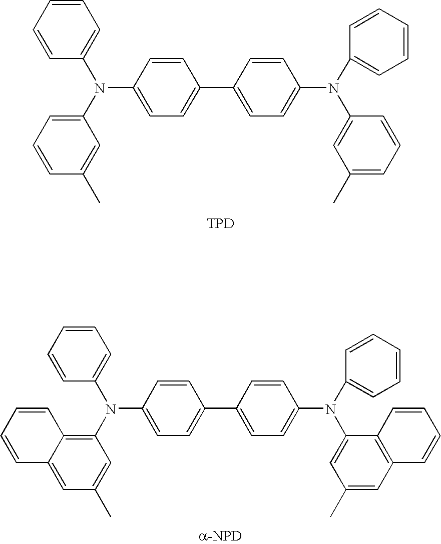

It will be understood by those of ordinary skill in the art that various changes in the thicknesses of the HIL and HTL included in the organic layer including the EML emitting blue light may be made depending on the desired properties of the EML.

The EML emitting blue, red or green light is formed on the HIL and the HTL. In one embodiment, the materials of the EML may be selected from emitting materials which are known to those of ordinary skill in the art, but are not limited thereto.

Examples of materials of an EML emitting red light may include 4-(dicyanomethylene)-2-methyl-6-(p-dimethyl aminostyryl)-4H-pyran (DCM1), [2-methyl-6-[2-(2,3,6,7-tetrahydro-1H, 5H-benzo[ij]quinolizin-9-yl)ethenyl]-4H-pyran-4-ylidene]propane-dinitrile (DCM2), Eu(thenoyltrifluoroacetone)₃ (Eu(TTA)₃), butyl-6-(1,1,7,7,-tetramethyljulolidyl-9-enyl)-4H-pyran (DCJTB), and the like. Meanwhile, an EML emitting red light may be formed by doping a dopant such as DCJTB on Alq3, by co-depositing Alq3 and rubrene and doping such a dopant, by doping a dopant such as iridium (III) bis(benzothienylpyridine)acetylacetonate (BTPIr) on 4,4′-N-N′-dicarbazole-biphenyl (CBP), and so on. It will be understood by those of ordinary skill in the art that various changes may be made to the EML emitting red light, depending on the desired properties of the EML.

Examples of materials for an EML emitting green light may include coumarin 6,10-(2-Benzothiazolyl)-2,3,6,7-tetrahydro-1,1,7,7,-tetramethyl 1-1H,5H,11H-[1]benzopyrano[6,7,8-ij]quinolizin-11-one (C545T, available from H.W.SANDS CORP., Jupiter, Fla.), quinacridone, Tris[2-(2-pyridinyl)phenyl-C,N]-iridium (Ir(ppy)₃), and the like. Meanwhile, an EML emitting green rays may be formed by doping Ir(ppy)₃ constituting a dopant, by doping coumarin-based materials constituting a dopant on Alq3 constituting a host and so on. It will be understood by those of ordinary skill in the art that various changes may be made to the EML emitting green light depending on the desired properties of the EML. Examples of the coumarin-based materials include compounds having formulae as below.

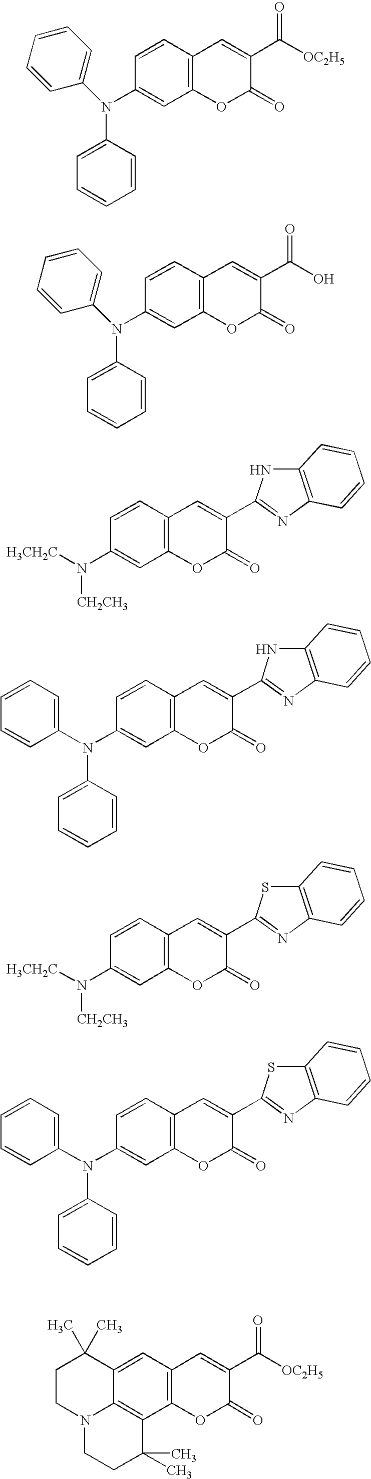

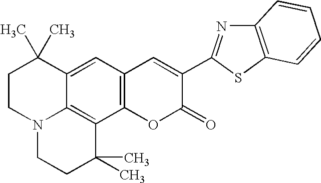

Examples of the materials of the EML emitting blue light may include oxadiazole dimer dyes (Bis-DAPOXP), spiro compounds (Spiro-DPVBi, Spiro-6P), triarylamine compounds, bis(styryl)amine (DPVBi, DSA), compounds (A)Flrpic, CzTT, anthracene, TPB, PPCP, DST, TPA, OXD-4, BBOT, AZM-Zn, BH-013X (all available from Idemitsu Kosan Co., Ltd., Tokyo, Japan), which is an aromatic hydrocarbon compound including naphthalene moiety, and the like. Meanwhile, the EML emitting blue light may be formed by doping IDE105 (available from Idemitsu) constituting a dopant on IDE140 (available from Idemitsu) and so on. It will be understood by those of ordinary skill in the art that various changes may be made to the EML emitting blue light, depending on the desired properties of the EML. Structures of some of these EML materials are set forth below.

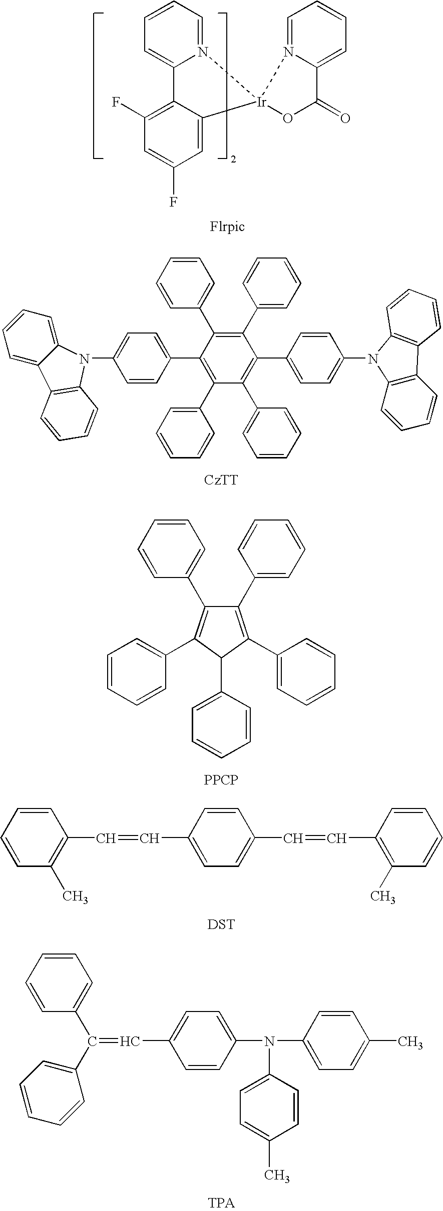

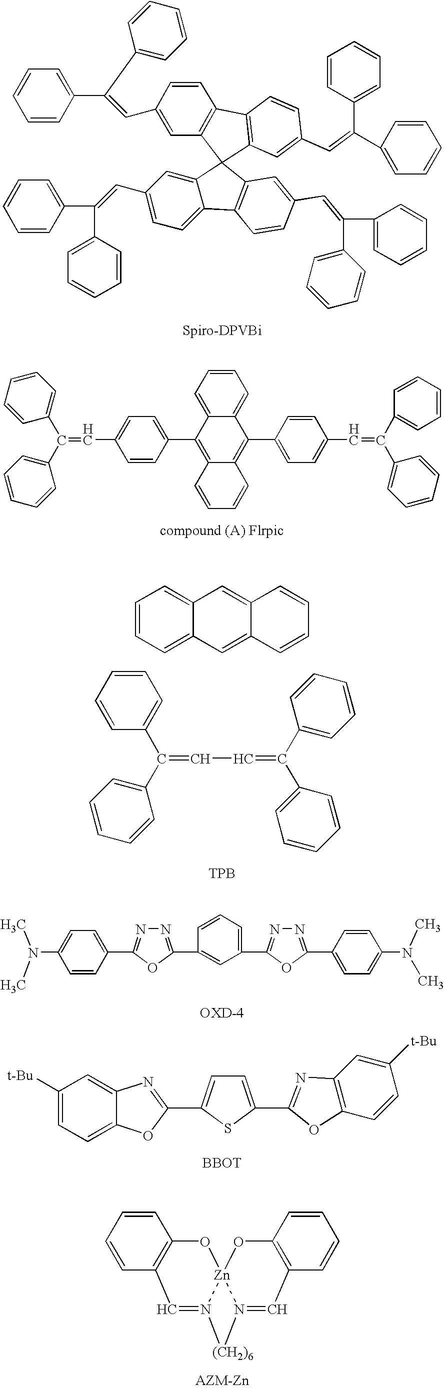

The thickness of the EML may be about 100 to about 500 Å, optionally, about 100 to about 400 Å. The respective thicknesses of the EMLs emitting red, green and blue light may be identical or different.

The HBL may be formed over the EML using various methods such as vacuum evaporation methods, spin coating methods, casting methods, LB methods, and the like. When the HBL is formed using vacuum evaporation and spin coating methods, deposition conditions and coating conditions differ according to compounds used in the HBL, but the deposition conditions and the coating conditions may be substantially the same as the deposition conditions and coating conditions used to form the HIL.

The materials for the HBL are not limited to specific materials. The materials for the HBL have electron transport capability and a higher ionization potential than an ionization potential of emitting compounds. The materials of the HBL may be bis(2-methyl-8-quinolato)-(p-phenylphenolato)-aluminum (Balq), bathocuproine(BCP), tris(N-arylbenzimidazole) (TPBI), and the like. In one embodiment, the thickness of the HBL may be from about 30 Å to about 60 Å, optionally from about 40 Å to about 50 Å.

The ETL may be formed over the HBL using various methods such as vacuum evaporation methods, spin coating methods, casting methods, LB methods, and the like. When the ETL is formed using vacuum evaporation methods and spin coating methods, deposition conditions and coating conditions differ according to compounds used in the ETL, but the deposition conditions and the coating conditions may be almost the same as the deposition conditions and coating conditions used to form the HIL. The electron transport materials may be Alq3, and the like. but are not limited thereto. The thickness of the ETL may be from about 100 Å to about 400 Å, optionally,from about 250 Å to about 350 Å.

The EIL may be formed using various methods such as vacuum evaporation methods, spin coating methods, casting methods, LB methods, and the like. When the EIL is formed using vacuum evaporation methods and spin coating methods, deposition conditions and coating conditions differ according to the compounds used in the EIL, but the deposition conditions and the coating conditions may be almost the same as the deposition conditions and coating conditions used to form the HIL.

The materials of the EIL may be BaF₂, LiF, NaCl, CsF, Li₂O, BaO, Liq, and the like, but are not limited thereto. The formula for Liq is set forth below.

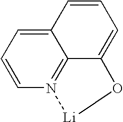

The thickness of the EIL may be from about 2 Å to about 10 Å, optionally,from about 2 Å to about 5 Å, optionally,from about 2 Å to about 4 Å.

Next, materials for forming the counter electrode are deposited on the EIL to form the counter electrode, thereby completing the OLED according to one embodiment.

The materials of the counter electrode may be a transparent metal oxide having excellent conductivity such as indium tin oxide (ITO), indium zinc oxide (IZO), tin oxide (SnO2), zinc oxide (ZnO), and the like. In addition, the counter electrode may be formed as a film using lithium (Li), magnesium (Mg), aluminum (Al), aluminum-lithium (Al—Li), calcium (Ca), magnesium-indium (Mg—In), magnesium-silver (Mg—Ag), calcium (Ca)-aluminum (Al), and the like. to be formed as a transparent electrode or a reflective electrode. It will be understood by those of ordinary skill in the art that various changes may be made to the counter electrode. The materials for forming the counter electrode are not limited to the metals as described above and compositions thereof.

The pixel electrode and the counter electrode serve as an anode and a cathode respectively, or vice versa.

While the OLED according to the embodiments and a method of manufacturing the OLED have been shown and described with reference to FIG. 1, it will be understood by those of ordinary skill in the art that the structure of the OLED is not limited to the structure illustrated in FIG. 1.

The OLED according to the instant embodiments may be applied to various types of flat displays, for example, passive matrix organic light-emitting display devices and active matrix organic light-emitting display devices. In particular, when the OLED according to the current embodiment of the invention is applied to active matrix organic light-emitting display devices, the pixel electrode may be electrically connected to a source electrode or a drain electrode of a thin film transistor included in the active matrix organic light-emitting display devices. The embodiments will now be described in further detail with reference to the following examples. These examples are for illustrative purposes only, and or not intended to limit the scope of the invention.

### EXAMPLE 1

An aluminum substrate and an ITO (available from Samsung SDI, Suwon, Korea) substrate, each having thicknesses of 1300 Å and constituting reflective pixel electrodes, were cut to sizes of 50 mm×50 mm×0.7 mm respectively. After being ultrasonic-cleaned in isopropyl alcohol and demi water for five minutes, the aluminum substrate and the ITO substrate were each UV-washed and ozone-washed for thirty minutes.

After a HIL having a thickness of 2000 Å was formed on each of the pixel electrodes using m-TDATA as a hole injection material, NPB as a hole transport material was deposited to form a HTL having a thickness of 200 Å on the HIL.

After an EML emitting blue light having a thickness of 200 Å was formed on the HTL using IDE140 (available from Idemitu) and IDE105 (available from Idemitu) as blue light-emitting materials, an ETL formed of Alq3 having a thickness of 250 Å was formed on the EML. MgAg having a thickness of 180 Å constituting a transparent counter electrode was formed on the ETL to complete the manufacture of an OLED, hereinafter referred to as “Sample 1”. Sample 1 included the HIL (2000 Å), the HTL(200 Å), the EML (200 Å) and the ETL (250 Å) to form an organic layer having a total thickness of 2650 Å.

### EXAMPLE 2

An OLED was manufactured using the same method as used in Example 1, except that a HIL having a thickness of 2200 Å was formed, hereinafter referred to as “Sample 2”. Sample 2 included the HIL (2200 Å), the HTL (200 Å), the EML (200 Å) and the ETL (250 Å) to form an organic layer having a total thickness of 2850 Å.

### EXAMPLE 3

An OLED was manufactured using the same method as used in Example 1, except that a HIL having a thickness of 2400 Å was formed, hereinafter referred to as “Sample 3”. Sample 3 included the HIL (2400 Å), the HTL (200 Å), the EML (200 Å) and the ETL (250 Å) to form an organic layer having a total thickness of 3050 Å.

### EXAMPLE 4

An OLED was manufactured using the same method as used in Example 1, except that a HIL having a thickness of 2600 Å was formed, hereinafter referred to as “Sample 4”. Sample 4 included the HIL (2600 Å), the HTL (200 Å), the EML (200 Å) and the ETL (250 Å) to form an organic layer having a total thickness of 3250 Å.

### EXAMPLE 5

An OLED was manufactured using the same method as used in Example 1, except that a HIL having a thickness of 2800 Å was formed, hereinafter referred to as “Sample 5”. Sample 5 included the HIL (2800 Å), the HTL (200 Å), the EML (200 Å) and the ETL (250 Å) to form an organic layer having a total thickness of 3450 Å.

### EXAMPLE 6

An OLED was manufactured using the same method as used in Example 1, except that a HIL having a thickness of 3000 Å was formed, hereinafter referred to as “Sample 6”. Sample 6 included the HIL (3000 Å), the HTL (200 Å), the EML (200 Å) and the ETL (250 Å) to form an organic layer having a total thickness of 3650 Å.

### EXAMPLE 7

An OLED was manufactured using the same method as used in Example 1, except that a HIL having a thickness of 3200 Å was formed, hereinafter referred to as “Sample 7”. Sample 7 included the HIL (3200 Å), the HTL (200 Å), the EML (200 Å) and the ETL(250 Å) to form an organic layer having a total thickness of 3850 Å.

### EVALUATION EXAMPLE 1

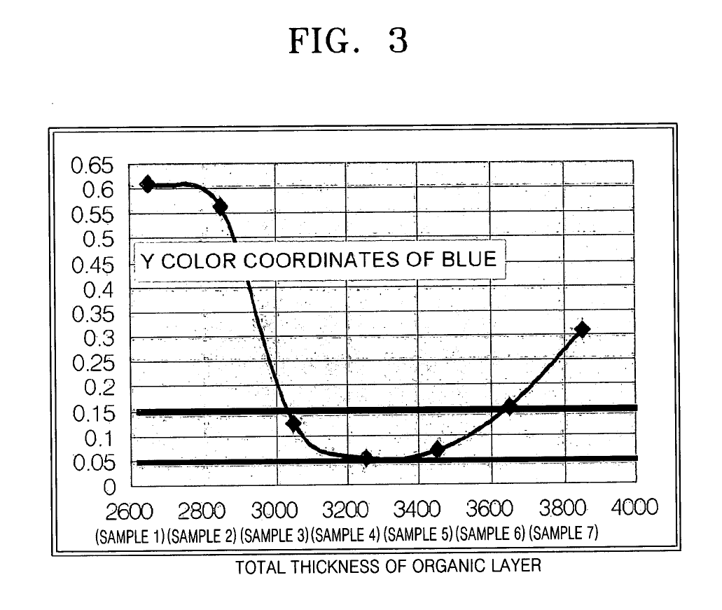

Emission spectrums, driving voltages, color coordinates, brightness and efficiencies of Samples 1 through 7 were measured using PR650® (Spectroscan spectrometer available from Photo Research, Inc., Chatsworth, Calif.) Source Measurement Unit, and these results are illustrated in FIG. 3 and Table 1. In particular, y color coordinates are illustrated in FIG. 3.

TABLE 1

| | | Current | | | Power | | |
|---|---|---|---|---|---|---|---|
| Sample | Voltage | indensity | Brightness | efficiency | efficiency | | |
| No. | (V) | (mA/cm²) | (cd/m²) | (cd/A) | (Im/W) | X value | Y value |
| 1 | 6 | 17.31738 | 920.2236 | 5.31387454 | 2.782338 | 0.1584 | 0.6085 |
| 2 | 6 | 15.79963 | 445.38 | 2.81892766 | 1.475987 | 0.2841 | 0.562 |
| 3 | 6 | 10.77688 | 96.47616 | 0.89521461 | 0.468733 | 0.2114 | 0.1237 |
| 4 | 6 | 6.81975 | 67.25238 | 0.98614143 | 0.516342 | 0.1502 | 0.054 |
| 5 | 6 | 9.611375 | 156.63672 | 1.62970147 | 0.85331 | 0.1354 | 0.0688 |
| 6 | 6 | 8.20625 | 230.67258 | 2.81093776 | 1.471804 | 0.1102 | 0.1543 |
| 7 | 6 | 7.2295 | 252.22212 | 3.48879065 | 1.826727 | 0.088 | 0.3098 |

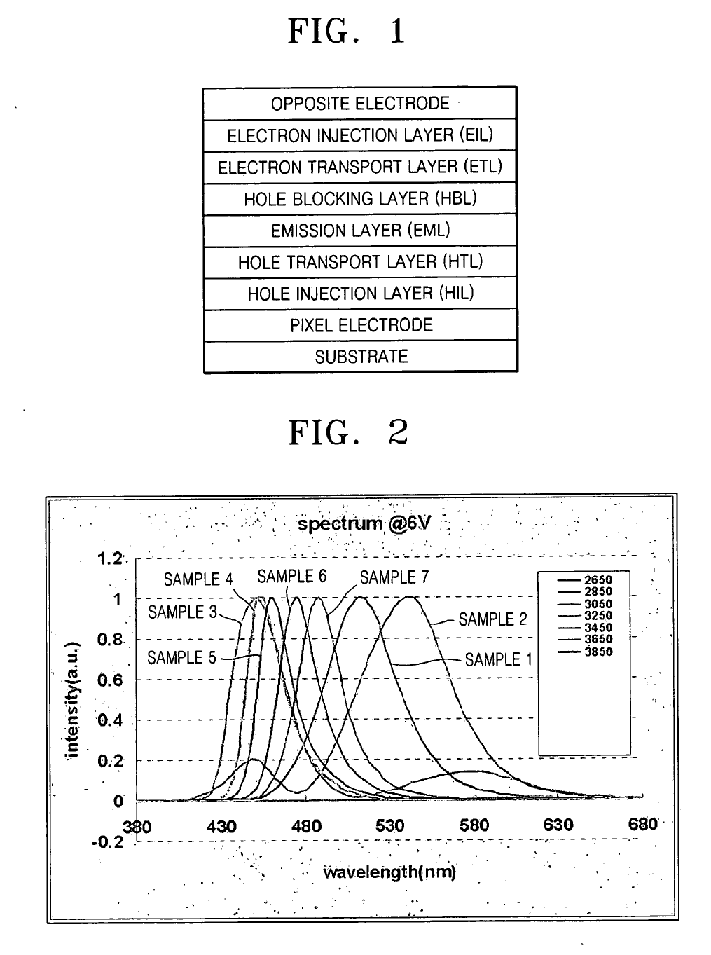

Referring to FIG. 2, Samples 3, 4 and 5 had a maximum emission wavelength of about 440-470 nm, which demonstrates that Samples 3, 4 and 5 had excellent emmission properties.

Meanwhile, referring to Table 1 demonstrates that Samples 3, 4 and 5 had excellent brightness, color purities and efficiencies. In particular, a y value indicates excellent color purities as illustrated in FIG. 3.

### EVALUATION EXAMPLE 2

An initial number of dark spots, a number of dark spots after driving for 3 hours, and a number of dark spots after driving for 15 hours of Sample 1 and 4 were each measured, and these results are shown in Table 2:

TABLE 2

| | Sample 4 | Sample 1 |
|---|---|---|
| Number of dark spots | 1 | 1 |
| Number of dark spots after | 1 | 9 |
| driving for 3 hours | | |
| Number of dark spots after | 1 | 15 |
| driving for 15 hours | | |
| Dark spot increment | 0 | 14 |

Referring to Table 2, the dark spot increment after driving for 15 hours in Sample 4 was 0. On the other hand, the dark spot increment after driving for 15 hours in Sample 1 was 14. From these results, it can be seen that the number of dark spots in the OLED according to the embodiments is remarkably reduced.

In the OLED according to the embodiments, the thickness of the organic layer including the EML emitting blue light is adjusted as described above, and thus the incidence of dark spots can be remarkably reduced without degradation of color purity and efficiency. A flat display including the OLED of the embodiments has improved reliability.

While the invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light-emitting device comprising:
a first electrode;
a second electrode; and
an organic layer interposed between the first and second electrodes, the organic layer comprising an emission layer emitting blue light,
wherein the organic layer has a thickness between about 3,000 Å and about 3,600 Å.

2. The device of claim 1, wherein the organic layer further comprises at least one layer selected from the group consisting of a hole injection layer, a hole transport layer, an electron blocking layer, a hole blocking layer, an electron transport layer and an electron injection layer.

3. The device of claim 2, wherein the organic layer further comprises a hole injection layer, a hole transport layer and an electron transport layer.

4. The device of claim 3, wherein a total thickness of the hole injection layer and hole transport layer is between about 2,400 Å and about 3,000 Å.

5. The device of claim 2, wherein the hole injection layer comprises at least one material selected from the group consisting of copper phthalocyanine (CuPc), triphenylamine (TCTA), m-MTDATA, Polyaniline/Dodecylbenzenesulfonic acid (Pani/DBSA) and Poly(3,4-ethylenedioxythiophene)/Poly(4-styrenesulfonate) (PEDOT/PSS).

6. The device of claim 2, wherein the hole transport layer comprises at least one material selected from the group consisting of 1,3,5-tricarbazolylbenzene, 4,4′-bis carbazolylbiphenyl, polyvinylcarbazole, m-bis carbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-il)-N,N′-diphenylbenzidine (α-NPD), N,N′-diphenyl-N,N′-bis(1-naphthyl)-(1,1 ′-biphenyl)-4,4′-diamine (NPB), poly(9,9-dioctylfluorene-co-N-(4-butylphenyl)diphenylamine) (TFB) and poly(9,9-dioctylfluorene-co-bis-(4-butylphenyl-bis-N,N-phenyl-1,4-phenylenediamin)) (PFB).

7. The device of claim 1, wherein the emission layer has a thickness between about 100 Å and about 500 Å.

8. The device of claim 7, wherein the emission layer has a thickness between about 100 Å and about 400 Å.

9. The device of claim 1, wherein the first electrode comprises a transparent material.

10. The device of claim 1, wherein the second electrode comprises a transparent material.

11. The device of claim 1, wherein the first and second electrodes comprise a transparent material.

12. The device of claim 1, further comprising a thin film transistor comprising source and drain electrodes, wherein the first electrode of the organic light-emitting device is electrically connected to one of the source and drain electrodes.

13. An organic light emitting display device, comprising:
an array of pixels, the pixels comprising a blue light emitting pixel,
wherein the blue light emitting pixel comprises:
a first electrode,
a second electrode, and
an organic layer interposed between the first and second electrodes, the organic layer comprising an emission layer emitting blue light; and
wherein the organic layer has a thickness between about 3,000 Å and about 3,600 Å.

14. The device of claim 13, wherein the organic layer further comprises at least one layer selected from the group consisting of a hole injection layer, a hole transport layer, an electron blocking layer, a hole blocking layer, an electron transport layer and an electron injection layer.

15. The device of claim 14, wherein the organic layer further comprises a hole injection layer, a hole transport layer and an electron transport layer.

16. The device of claim 15, wherein a total thickness of the hole injection layer and hole transport layer is between about 2,400 Å and about 3,000 Å.

17. The device of claim 13, wherein the emission layer has a thickness between about 100 Å and about 500 Å.

18. The device of claim 17, wherein the emission layer has a thickness between about 100 Å and about 400 Å.

19. The device of claim 13, wherein the pixels further comprise a red light emitting pixel comprising an organic layer which comprises an emission layer emitting red light, and wherein the organic layer has a thickness between about 2,700 Å and about 3,300 Å.

20. The device of claim 13, wherein the pixels further comprise a green light emitting pixel comprising an organic layer which comprises an emission layer emitting green light, and wherein the organic layer has a thickness between about 2,200 Å and about 2,800 Å.
